(19) United States
(12) Patent Application Publication
(10) Pub. No.: US 2004/0248381 A1
(43) Pub. Date: Dec. 9, 2004

(54) Nanoelectronic interconnection and addressing

(76) Inventor: James J. Myrick, Glencoe, IL (US)

Correspondence Address: James J Myrick, 748 Greenwood Avenue, Glencose, IL, 60022, US

(21) Appl. No.: 10/479,032

(22) PCT Filed: Nov. 1, 2001
(86) PCT No.: PCT/US01/44792

Related U.S. Application Data
(60) Provisional application No. 60/245,013, filed on Nov. 1, 2000.

(51) Int. Cl. H01L 21/301

(52) U.S. Cl. 438/460

(57) ABSTRACT

Methods and devices relating to nanoscale electronics, including fabrication and addressing of molecular electronics.

### FIELD OF THE INVENTION

The present invention relates to nanofabrication and nanoscale electronic and molecular electronic devices and systems.

### BACKGROUND OF THE INVENTION

A wide variety of organic compounds have been designed for molecular electronics, such as those illustrated in FIG. 1 and described in R. Dagani, “Building From the Bottom Up”, (C&EN) Oct. 26, 2000, pp. 27-32 (all citations referred to herein are incorporated by reference). Such molecular electronic compounds may be readily designed as two-terminal devices (such as reversible or irreversible memory elements, diodes, negative differential conductivity or merely uniformly conductive molecular “wires”. Molecular electronic compounds may also be provided as three, four or more terminal devices with more complex logic or electronic functionability. Three terminal molecular compounds are known and can be readily designed, in which the conductivity through the compound between two terminals (e.g., source and drain terminals having a predetermined 1-5 volt potential difference is modulated by the potential applied directly to a third terminal of the molecular compound. Such organic compounds may have functional groups such as thiols, aromatic carbon, isocyanide, isothiocyanide, carboxylate, bpy-Ru(NCC)₂ groups, phosphono, etc. (shown by the designation “G” in FIG. 1) which can be used to self-assemble the molecular electronic compounds in appropriate orientations adjacent selected surfaces which bond chemically with the functional groups. (See, e.g., U.S. Pat. Nos. 5,589,692, 5,475,341, 6,128,214 and references cited therein; see also, J. C. Ellenbagen, et al., “Architectures for Molecular Electronic Computers: 1. Logic Structures and an Adder Built from Molecular Electronic Diodes”, Mitre publication MP 98W0000 183, July, 1999, http:/www.mitre.org/technology/nanotech; “A Brief Overview of Nanoelectronic Devices, Mitre Publication MP 98W0000024, January, 1998-GOMAC98). Similarly, a molecular scale transistor has been fabricated at Bell Labs by H. Schon, Z. Bao and H. Meng, (as reported in Nature, 413, pp. 667-668, Oct. 18, 2001), using a dithiobiphenyl compound which is responsive in conductivity to an external electric field (see FIG. 1h).

However, these organic molecular electronic compounds are extremely small (e.g., typically 2-50 nanometers in length), well below the conventional design rule dimensions of semiconductor electronics, which limits development of dense nanoelectronic array fabrication and interconnection of multiple terminal (e.g., 3 or more) connections to make functional compounds. Those working in this field hope that, somehow, molecular electronic devices can “self-assemble” into somewhat defective arrays which will nevertheless be able to function usefully because of redundant design. These problems may be referred to as the “Addressing Problem” and the “Interconnection Problem.” A nanocomputer or a nano memory device should contain an enormous amount of large devices and information in a very small volume which must be addressed, controlled and coordinated in a precise manner. New technologies for solving the “Addressing Problem” and the “Interconnection Problem” are clearly needed for such input/output, addressing and control.

### SUMMARY OF THE INVENTION

The present invention is directed to nanoscale layered wafers, and methods of preparing such wafers, and to nanoscale electronic devices and methods utilizing such wafers. By depositing multiple layers of different materials to form a laminate having layer thicknesses in the range of, for example, from 1 nanometer to 100 nanometers (preferably 2 to 5 nanometers), and slicing the laminate across the layers to form wafers, for example, from about 5 microns to about 300 microns in thickness, columnar wafers can be produced which have sheets of individually and precisely controllable nanometer scale dimensions. The wafers have zones across their surfaces which correspond to the nanometer-scale thicknesses of the deposited layers. These zones can be used in a wide variety of ways in the fabrication of nanoscale electronic, fluidic and MEMS devices. By using a single columnar wafer, nanoscale addressing and interconnection can be made at least to one dimension. By utilizing two such columnar wafers, at least two-dimensional nanoscale addressing and interconnection can be facilitated.

### DESCRIPTION OF THE DRAWINGS

FIGS. 1a-h are illustrations of a variety of conventional molecular electronic compounds of the type designed for self assembly in molecular electronic devices of which

FIGS. 1a and 1b are 4-terminal polythiophene compounds;

FIG. 1c is a 2-terminal Catenane;

FIG. 1d is a 2-terminal diode molecule (with its diode symbol);

FIG. 1e is a 4-terminal “or” gate molecule with its electronic symbol and its polydentate symbol;

FIG. 1f is a 4-terminal “and” gate molecule with its electronic symbol and its polydentate symbol;

FIG. 1g is diffuse-terminal, switchable [2]catenane for solid-state molecular switching devices;

FIG. 1h is a representation of the Bell Labs molecular transistor;

FIG. 2 is a schematic perspective illustration of a multi-layer “boule”, and a wafer saw for the boule;

FIG. 3 is a top view of 2 different types of (the wide variety of) of layers which may be used to form the multi-layer boule of FIG. 2;

FIG. 4 is a top view of electrode cathode layer pattern for use in a patterning layers of boules such as that illustrated in FIG. 2;

FIGS. 5a-5h are sequential illustrations of one type of layer processing for Titanium-based layers for boules such as those of FIG. 2;

FIG. 6 is a top view of an embodiment of conductor layer patterns for multi-layer boules such as those of FIG. 2, illustrating the positioning of conductor and insulator zones, and back side connector position at the locations of the wafer saw cuts, for facilitating addressing of nm-scale layer widths at the front surface of boule slices;

FIG. 7 is an illustration of the back side of a wafer slice, showing photolithographically fabricated conductor connections for uniquely addressing adjacent pairs of nanolayer conductor sheets at the front side of the wafer;

FIG. 8 is an illustration of the back side of a wafer slice like that of FIG. 7, showing photolithographically fabricated “source” and “drain” power-voltage conductor connections for nanoconductor terminals at the front side of the wafer;

FIGS. 9a-d are perspective schematic illustrations of molecular electronic compounds self assembled at the front face of a wafer like that of FIG. 7, with arrows illustrating their conductivity directions and connecting points;

FIG. 10 illustrates an embodiment of a simple, addressable, 2-dimensional array (suitable for simple molecular electronic memory designs) in which it molecular electronic compound connects the points of intersection of two adjacent polished wafer slices which are rotated with respect to each other to provide orthogonal intersection zones;

FIG. 11 is a cross-sectional view of a simple cross-cut wafer having nanospaced Titanium layers separated by a distance designed to accommodate a specific molecular electronic compound;

FIG. 12 it is a perspective illustration of another embodiment of a wafer-conductor designed, in which source and drain electrodes are provided as a prison described, and in which intermediate electrodes are also provided which are photolithographically defined along the conductor dimension;

FIGS. 13a-d are sequential cross-sectional views illustrating selective surface etching to prepare zones for self assembly of molecular electronic compounds;

FIG. 14 is a sectional view of the device of FIG. 13D., taken in the direction of line 14-14;

FIG. 15 is another cross-sectional view like that of FIG. 13, which illustrates self assembled molecular electronic compound layers which may be used to connect, or disconnect or “this assembled” previously connected layers of a wafer face adjacent thereto;

FIG. 16 is similarly the cross-sectional illustration of self aligned, this assembly zones of adjacent, orthogonal a rotated wafer faces in which three-self-assembled molecular electronic molecules on the respective faces are reacted or displaced by reacted molecules on adjacent wafer face, to provide a two-dimensional fabrication tool;

FIG. 17 represents a side view and aligned top view of a nanolayered wafer surface having a variety of nanoscale conductors, dielectrics and molecular electronic compounds selectively assembled thereon;

FIG. 18 is a partially transparent view like that of FIG. 17 also illustrating its intersection with a second orthogonally rotated wafer, also having a multiplicity of nanoscale surfaces with differently-functional compounds self assembled respectively thereon, showing the zones for isolation and interaction which made of the defined in this manner;

FIG. 19 is an illustration of molecular electronic “or” and “and” gates which may be fabricated using orthogonal or rotated wafer faces as described herein; and,

FIG. 20 is a schematic illustration of a conventional logic gate and its dimensions, together with a corresponding nanoscale molecular electronic logic gate which may be fabricated using orthogonally rotated and facing cross-cut wafers with appropriate self-assembly and self disassembly molecular compounds in accordance with the present invention.

### DETAILED DESCRIPTION OF THE INVENTION

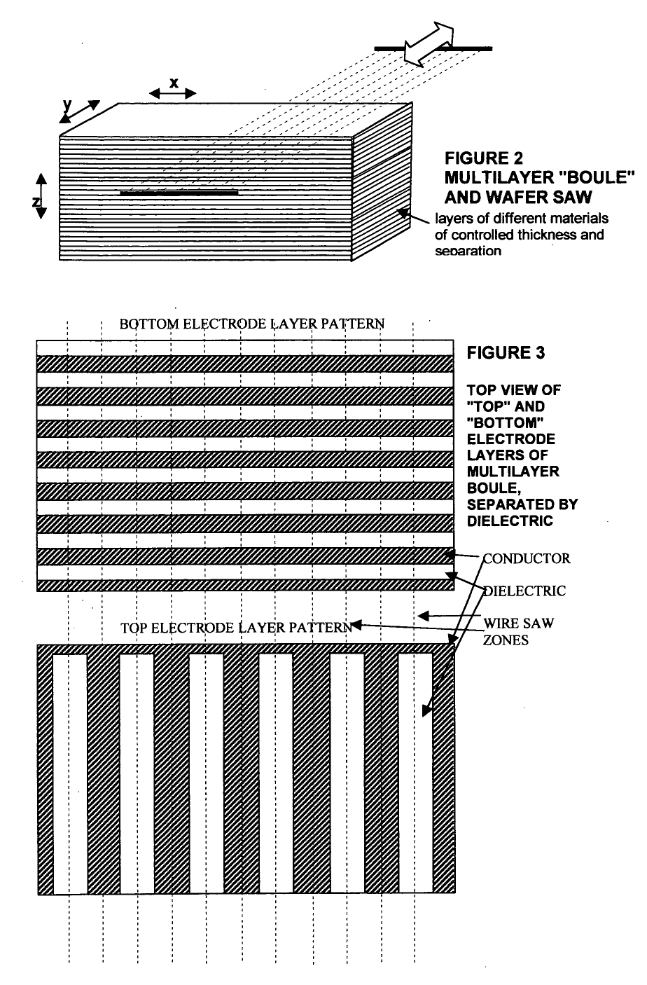

As shown in FIG. 2, dielectric, conductive and semiconductive layers can be deposited by a variety of processes, including physical vapor deposition, chemical or reactive vapor deposition, molecular beam epitaxy, sputtering, electrodeposition and laser ablation. The thickness of deposited conducting and insulating layers can be precisely controlled in the thickness dimension (z) on an Angstrom scale. Conductor and insulator layers can be defined, patterned and fabricated in the other two dimensions (x and y) on a photolithographic scale (0.1-10 microns) using conventional integrated circuit fabrication techniques. This is important for making front side or back side connections, as will be described. The multilayer “boules” may be sawed into wafers by cutting across the layers by a suitable wafer saw, as shown in FIG. 2.

The wide range of parameters of wafer layer materials, wafer layer thickness and separation, abutting wafer design and orientation, and fabrication technologies of the present invention can be used to fabricate a wide variety of addressable, nanoscale devices.

A wide variety of different materials may be used in the layers of the wafers. Examples of such materials include:

| Material | Utility and Functionality |
|---|---|
| Titanium | Metal conductor, selective for carbon |
| | attachment |
| Aluminum | Easily deposited, processing well developed |
| Gold and gold alloys | Selective for —SH attachment |
| (e.g., Cr—Au—Cr | |
| N− Silicon | Silicon surface chemistry for selective |
| | bonding, easily deposited, permits modulation |
| | by adjacent electric fields and conductors |
| P− Silicon | Silicon surface chemistry for selective |
| | bonding conductivity may be modulated by |
| | adjacent conductors. |
| N+ Silicon | Silicon surface chemistry, conductivity not |
| | affected by fields |
| P+ Silicon | Silicon surface chemistry, conductivity not |
| | affected by fields |
| Semi-insulating Si | Silicon surface chemistry, no long-range |
| | conductivity |
| Ge, SiGe | Same as for Si |
| GaAs and other III-V | Molecular beam epitaxy, high electron |
| and II-VI semi- | mobility, electro-optical capability |
| conductors with wide | |
| band gap variability | |
| including insulators | |
| SiC-conducting | Same as for Si - provides hard layer for |
| | polishing |
| SiC semi-insulating | Same as for Si - provides hard layer for |
| | polishing |
| Silicon dioxide | Easily deposited or grown, etch-selectivity |
| (deposited or grown), | well developed, X-Ray transparent |
| Silicon nitride (deposited | X-Ray transparent, easily deposited, etch |
| or grown) | selectivity well developed |
| Aluminum, titanium, | X-ray transparent, easily deposited or grown |
| other oxides and nitrides, | |
| oxynitrides, etc. | |
| CaF₂ and other epitaxial | With selective conductors and |
| monocrystalline insu- | semiconductors, permits epitaxial |
| lators for specific | monocrystalline layer control |
| conductors | |
| Superconducting cuprates | low temperature superconducting layers |

As described, the layers may be patterned (in the x and/or y direction) to facilitate photolithographic interconnection, for example, alternating layers of “top electrodes” and “bottom electrodes” such as shown in FIG. 3, separated by insulating layers, are built up by sequential deposition and patterning on a suitable substrate, such as monocrystalline silicon, sapphire or alumina. The minimum x, y dimension of two-dimensional patterning of the layers is in the conventional IC range (e.g., 0.1-10 microns). The thicknesses of the layers, and in particular, the dielectric separating the conductor pattern layers, is on a molecular electronics scale, as will be described. Hundreds-to-thousands of layers are deposited in suitable thickness arrangements, such as shown below, designed for cross-cutting with wafer-cutting wires or saws. The thickness of the layers, the materials used, and their conductor pattern is designed for subsequent self-assembly, and to interface between a molecular dimension, and integrated circuit fabrication dimensions (0.1-10 microns). The layers may be epitaxially monocrystalline (e.g., silicon and isomorphorus silicide conductors or CaF₂ insulator layers) or other deposited films of metal (e.g., gold, aluminum, titanium, titanium silicide, etc.) and insulating dielectric (deposited and grown oxides, nitrides, organic films, etc.). The layers should be sufficiently strong and adherent to each other to maintain integrity through subsequent wafer slicing and polishing steps.

An important practical feature of various embodiments of the present method is that large surface areas can be processed and layered in uniform deposition equipment. Thus, while each individual layer is relatively thin, relatively large volumes of functional wafer material may be built up in a reasonably practical time frame. In addition, by depositing the designed layer arrays on substrates which may be subsequently separated from the layers (e.g., by dissolution or lift-off), relatively thin arrays may be “stacked”, and subsequently molecularly bonded, to form thick boules for subsequent slicing.

Nanolayer wafers can also be made using deposition, and selective anodization and etching of metals such as aluminum and titanium. In this regard, inert cathodes can be patterned to match the desired metal layer addressing patterns for wafer cutting, and merely shifted between layers to make fabrication easy. The tolerances can be relatively large for such anodization, within the scale of the crosscut wafer wire kerf dimensions. Very large areas can be layered in this way, cut, stacked (after separation from the original substrate layer if desired) and adherently bonded (e.g., electroglass, thermal, etc) to make thick Boules with hundreds or thousands of layers:

Two-Dimensional Molecular Scale Self-Addressed Systems

Because these conductor layers of an adjacent wafer face may have molecular-scale separation thicknesses, this extends the one-dimensional transition to molecular scale previously described, to 2 dimensions. When combined with appropriate addressing, which will now be described, this is a very powerful fabrication technique which can utilize and address molecular scale electronics in 2 dimensions, to produce enormous device density.

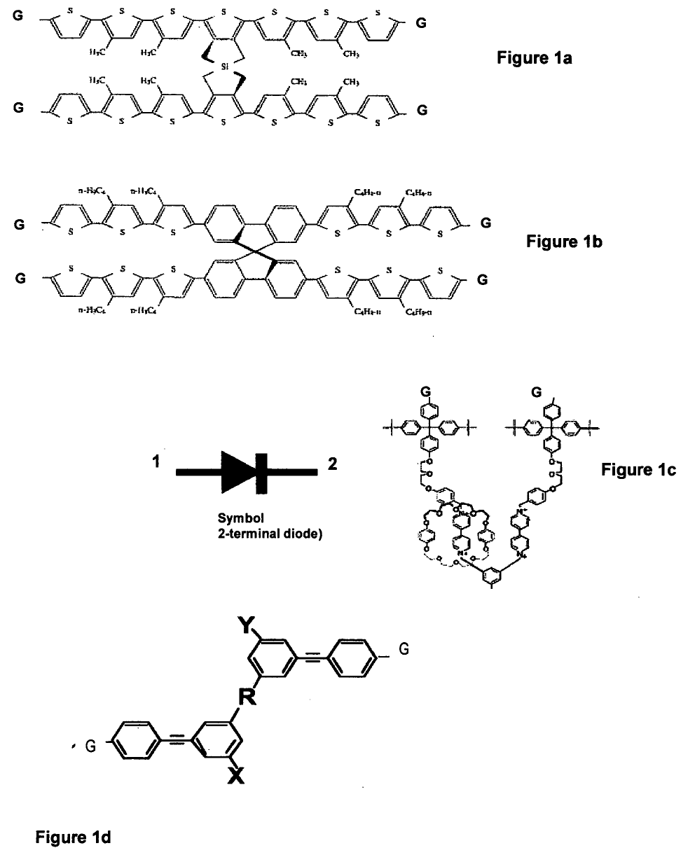

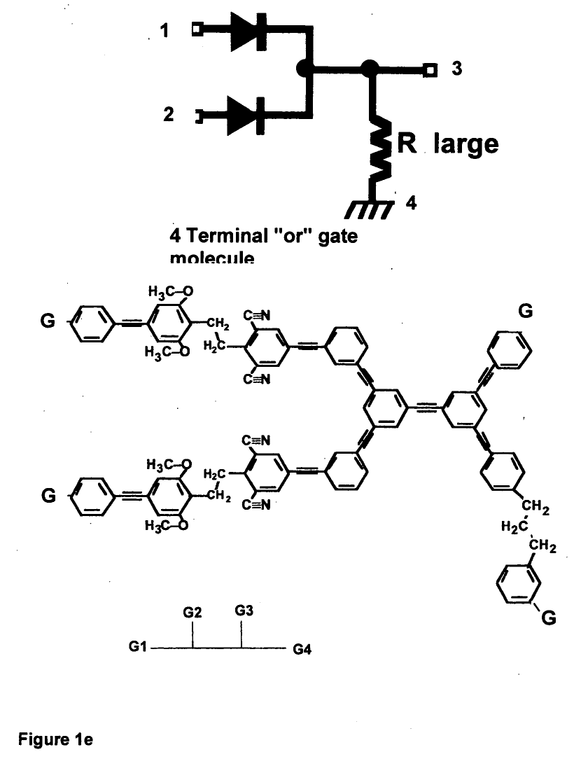

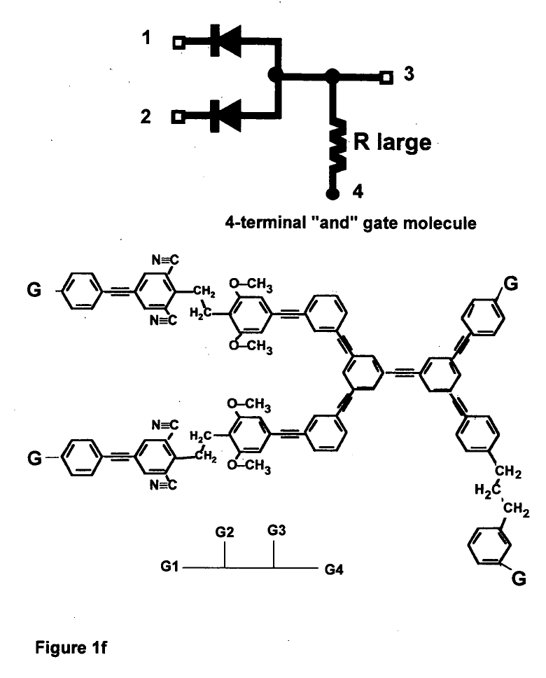

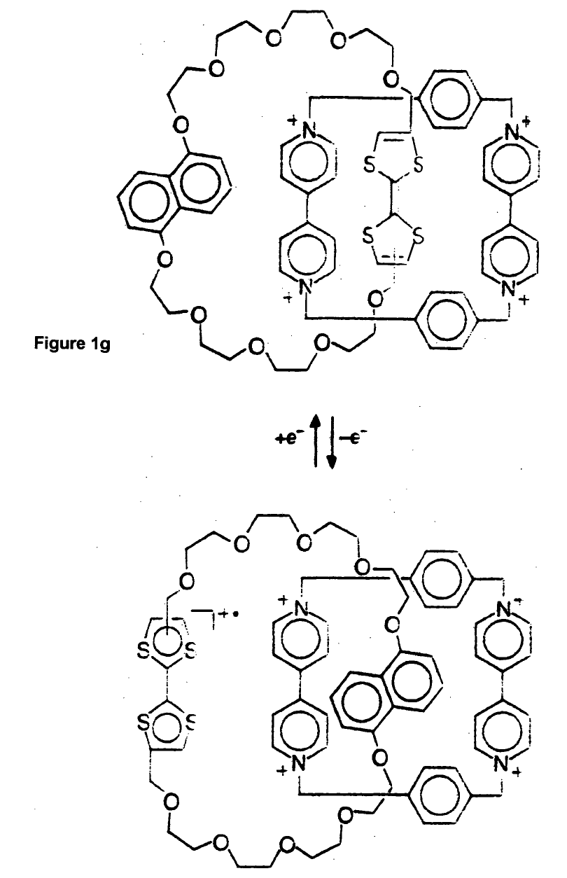

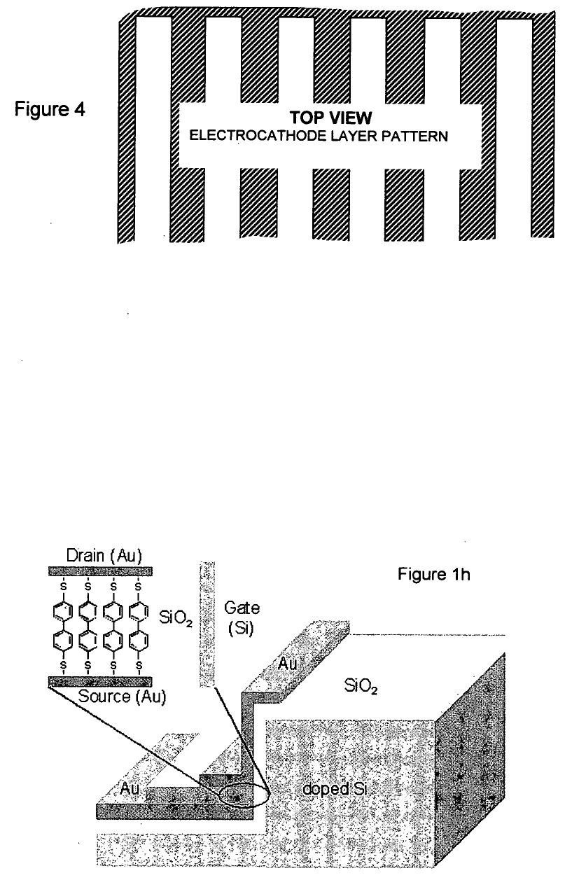

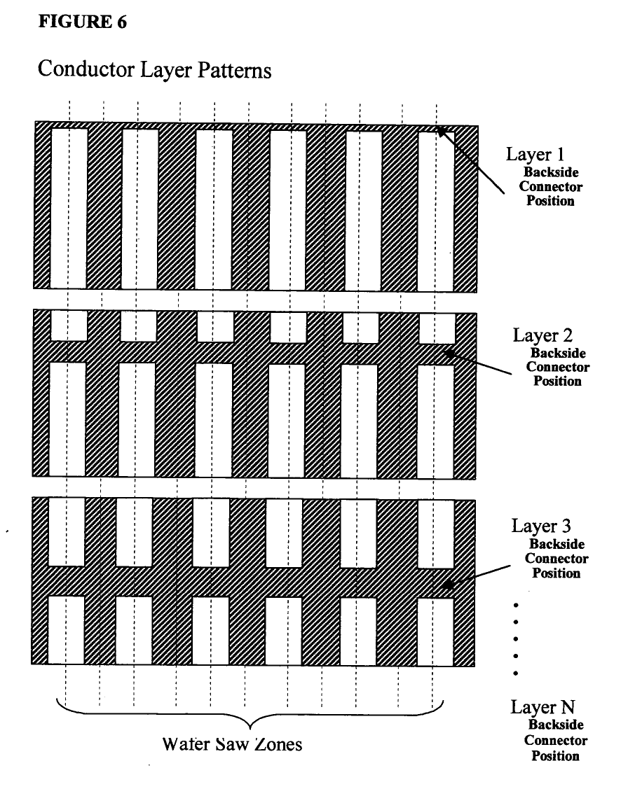

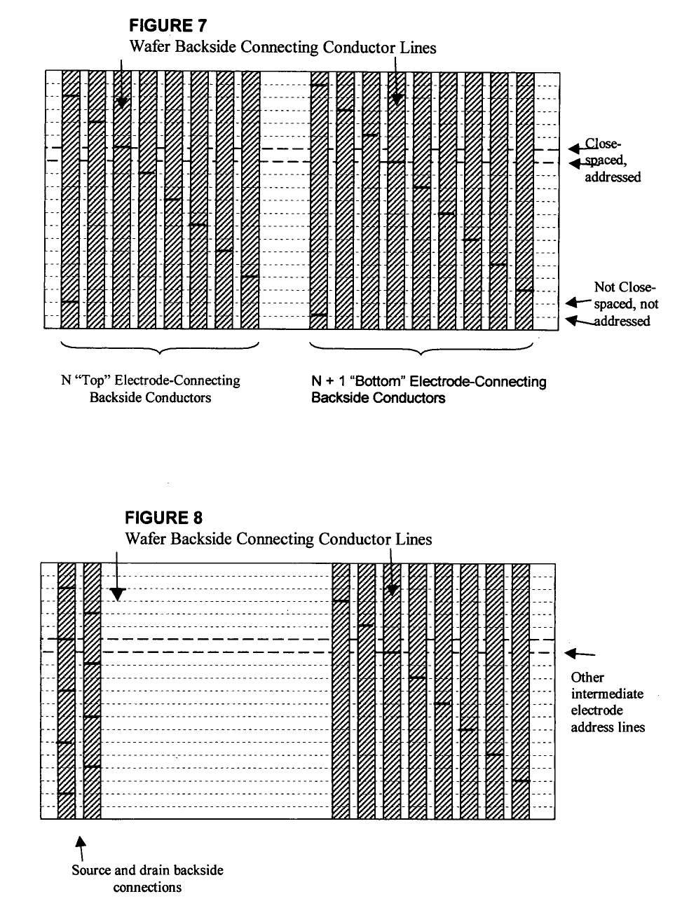

FIG. 6 shows a series of electrode layer patterns (like FIG. 2), in which each electrode is designed to have a different backside connector position when stacked as in FIG. 1, and sliced into wafer form. The backside connectors have a width which is easily addressed by standard photolithography (e.g., 1-10 microns). When sliced and stacked, they may be connected to and addressed by backside electrodes, as shown in FIG. 7.

Particularly for relatively small numbers of layers, there may be one unique backside address line for each “top” electrode, and each “bottom” electrode. However, for addressing more ultrathin layers, the electrodes may be connected in repeating patterns, by having a number “N” of backside address lines and respectively corresponding electrode patterns for one electrode, and “N+1” address lines for the other electrode, a much larger number of molecular scale layers can be addressed uniquely [approximately (N*N+1)]. This is a very important capability for ultrahigh density molecular-scale addressing, from integrated circuits scale address lines. Backside contacts may also be made in a similar manner to provide periodically spaced “source” and “drain” electrodes across the wafer face in a desired arrangement.

While FIG. 8 shows adjacent “source” and “drain” electrodes using only 2 layer patterns with precise aligned backside positions, intermediate, separately addressable electrodes may also be included between the “source” and “drain” electrodes, as well as a variety of patterns of different dielectric materials for absorption of different functional moieties of multi-terminal molecular electronic compounds.

Slice Wafers From “Multilayer Boule”, and Polish Sliced Wafers

Fabricated layers can be sliced to prepare wafers for subsequent processing. A “multilayered boule” like that of FIG. 2 may be sliced in any suitable manner, such as by using diamond saw wires, such as used in slicing silicon wafers from a monocrystalline silicon boule. The sliced wafers may be, for example, 10-300 microns thick. The cross-cut wafers are polished to at least optical smoothness (e.g., by cloisonné and/or damascene chemical mechanical polishing techniques), to produce flat, smooth wafers for subsequent fabrication steps. To preserve the integrity of the wafer layers, the wafers may be temporarily bonded to a backing layer, e.g., of monocrystalline silicon or sapphire, while the opposite face is polished. Plasma, vacuum or sputter cleaning may also be used to prepare the surfaces for subsequent fabrication steps.

Self-assembly and post-reactive materials As indicated, the layer thicknesses of the Boule, and the corresponding separations of the exposed surfaces of the sliced and polished wafters, may be designed and determined by the thickness(es) of the deposited layers, and the slicing angle across the layers (preferably in the range of 45-90 degrees). After preferably polishing and etching the sliced wafers, a wide variety of organic, inorganic and molecular electronic components can be applied, to self-assemble in predetermined locations controlled by the surface chemistry of the polished and/or etched wafer faces, using functional groups which are selectively reactive with or otherwise adsorbed on specific layers, in accordance with conventional practice in molecular electronics.

Self assembly materials, “self-disassembly” materials, activating materials, deactivating materials, and a variety of functional molecular electronic materials can be selectively applied to the various respective wafer faces, utilizing the specific surface characteristics of the wafer face layers to precisely and selectively position the desired materials at specific layers with molecular precision.

The self-assembly materials may include

molecular insulator layers to prevent electrical contact between conducting lines of abutting wafer faces,

1, 2 and 3-dimensional organoconductors,

Functional 1, 2, 3 and 4-terminal molecular electronic compounds (see Tour et al PCT application WO 00/44094 published Jul. 27, 2000). Rotoxanes and other molecularly functional compounds may be interconnected. These compounds may be designed to react with compounds or surfaces on an opposite wafer face to complete terminal connections at molecularly precise locations.

Activating materials such as dopants for potentially conductive materials on an opposite wafer face, such as polyaniline, polypyrrole and co-facial conductive compounds (see U.S. Pat. Nos. 4,662,170; 4,563,300; and 4,563,301). This creates a self-aligned, activated zone, which can be directly addressed, or which can be designed to connect with other molecular scale zones.

Selectively deactivating materials may be selectively applied to one designed wafer face for compounds on the opposite wafer face, such as dopant-removal compounds and pH-changing compounds. For example, anionic or cationic materials such as carboxylic acids or amines may be used to selectively withdraw dopants from a doped organic conductor or semiconductor on the opposite wafer face. Compound which displace the bonding may also be used.

Nonselective deactivating materials for self-assembled materials on an opposite wafer face, such as peroxides and other highly oxidizing materials. Such materials can be used to isolate functional cells at the intersecting wafer interface.

Nanotubes, metal rods and similar self-addressed devices may be incorporated in etched packet zones.

Layer Thickness and Separation

The layer thickness may be precisely controlled with near-atomic precision to achieve desired separation distances, selectable conductivity, (conductor, semi-conductor, insulator), desired electrical functionality, and surface chemistry. The layers may be deposited in repetitive patterns, and/or specifically tailored and varying patterns for different functional systems. Different layer patterns and self-assembly compounds may be abutted against each other to achieve post-assembly and selective reaction, to prepare 2-dimensional arrays of molecular-scale devices. By isolating cells forms by the interface between two wafer-faces, “self assembled” circuit cells may be fabricated and interconnected, as desired. These may be addressed by backside IC addressing, and may also be interconnected along the intersecting wafer faces, at molecularly small dimensions

The formation of molecular-scale connections by layered wafers may be demonstrated by depositing single, and double Ti layers about 100-500 Angstroms thick between silica layers, mounting the layered substrate in a matrix, crosscut, lap and polish it, and they etch. The single Ti layer is plasma etched in chlorine-containing gas, to expose clean Ti metal for subsequent reaction, and preferentially to remove 5-10 angstroms of Ti. The double layer is very briefly etched in a weak silica etchant to preferentially remove 10-20 microns of SiO2, and plasma etched to expose clean Ti metal. The single Ti layer wafer is treated with a Ti-selective molecular electronic compound, followed by a bifunctional silanol coupling agent. The wafer is then compressed against a similar, clean wafer face, which has not been treated with the molecular electronic compound, or the silanol coupling agent, to couple them:

A two-layer Ti wafer may have one Ti layer separated by a thickness of SiO2 corresponding to the length of the molecular electronic compound, to demonstrate the ability to join two precisely-separated metal conductors with a molecular electronic compound.

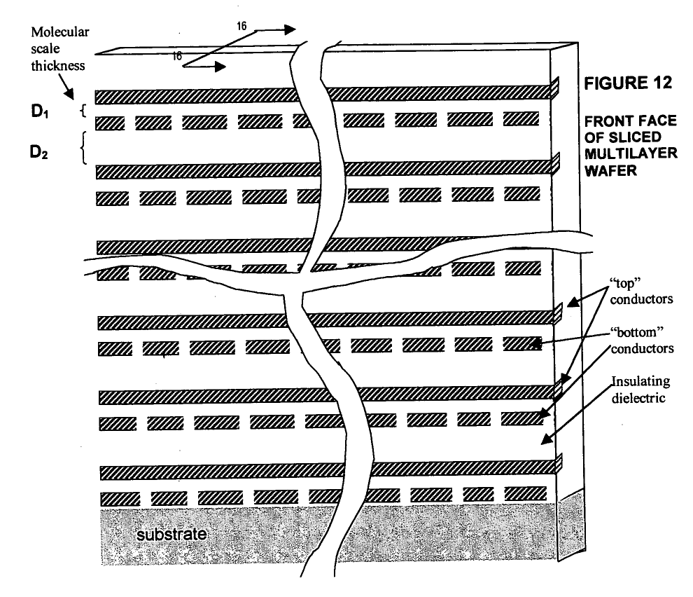

One face of another embodiment of a sliced wafer from a Boule like that of FIG. 2 with appropriately patterned conductor layers is shown in FIG. 12.

The electrode layers are patterned with a first distance D1, which is the precise, angstrom-scale distance corresponding to the length of a selected self-assembly molecule, such as:

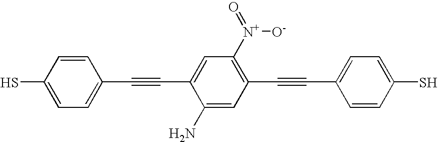

Other 2, 3, and 4 terminal molecular electronic compounds are described in PCT Application WO 00/44094 published Jul. 27, 2000. Particularly desirable 2, 3, and 4-terminal molecular electronic compounds may include viologen and/or polymerized aniline segments which are stable at room temperature, and which are reversible oxidized and reduced at relatively low voltages (e.g., plus or minus 2 volts). As indicated above, thiophenyl compounds, which couple well to gold surfaces may be used as molecular compounds having a conductivity which may be varied by application of an external electric field from a gate electrode for transistor fabrication:

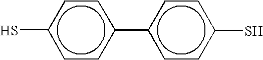

For example, the following new 2-terminal molecular electronic compound(s) may be switched between more-conductive, and less-conductive states:

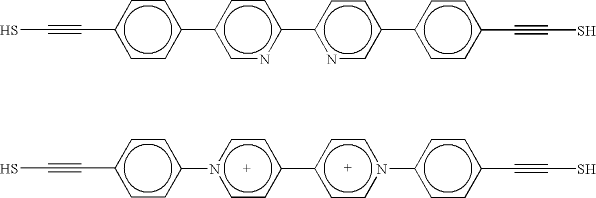

Pi-conjugated bipyridine functionality, including 5,5′-diethynyl-2,2′-bipyridine moieties, may be obtained in high yield from 5,5′-dibromo-2,2′-bipyridine by treatment with trimethylsilyl acetylene in the presence of the Pd(PPh3)2Cl2 catalyst Synthesis of dibromobipyridine may be accomplished by treatment of 2,2′-bipyridine.HBr with Br2 at high temperature under pressure (as reported by Ziessel et. al., F. M. Romero and R Ziessel, Tet Lett., 36 (1995) 6471], or by a modification of the synthesis of 5,5′-dichloro-2,2′-bipyridine. from 2,5-dibromopyridine, as reported by. K. D. Ley and K S. Schanze, “Photophysics of Metal-Organic [pi]-Conjugated Polymers”, (http://web.chem.ufl.edu/˜kschanze/papers/photo_physics/1997). Viologen preparation is similarly well-known.

The distance D2 may be substantially larger, e.g., 0.5 to 5 microns, to permit integrated circuit-scale back-side interconnection and addressing. As shown in the following FIG. 4, which is a cross-sectional view of FIG. 3, crosscut, layered wafer faces may be polished to nanometer-or-better scale flatness by CMP, and the dielectric may be simultaneously and/or subsequently selectively etched a predetermined distance, on the Angstrom scale, if desired, to expose protruding conductor-defined zones separated by the distances D1 and D2 corresponding to the thicknesses of the dielectric layers prospectively separating the “top” and “bottom” electrode layers. The D1 distance precisely matches the length of a selected molecular electronic compound.

Apply Molecular Self-Assembly Compounds and Address/Control Lines

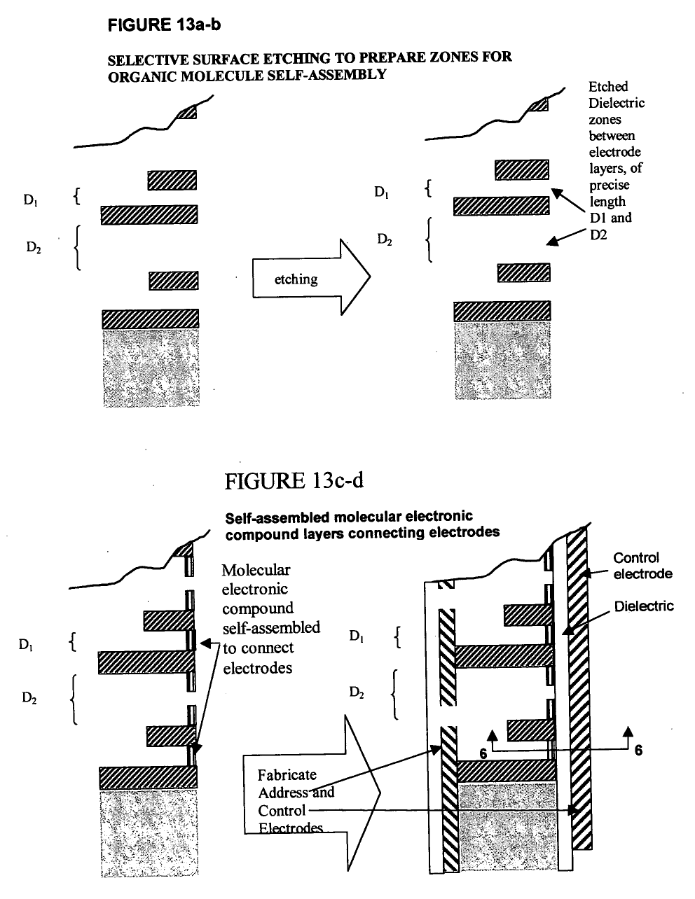

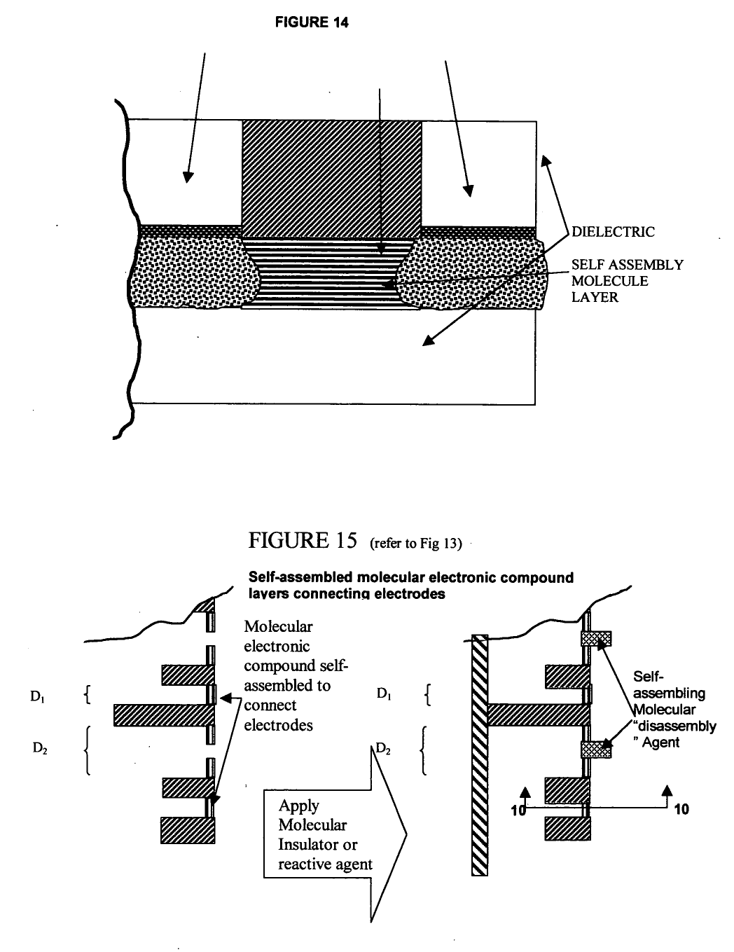

Upon treatment of the etched surface with the self-assembling molecular electronic compound, the conductors are surface-coated, and the top and bottom electrodes are connected, while no connection is made along the D2 zone, as shown in FIG. 13. The depth of the molecular compound layer may be precisely controlled by the depth of the etching treatment, and may range from a monolayer, to several thousand Angstroms or more:

Subsequent deposition and patterning of dielectric and control electrode layers over the D1 zones can produce “three-terminal” devices.

The “top” and “bottom” electrodes may be addressed along the back or opposite side of the wafer by suitable IC scale conductors, and the “bottom” electrodes may be connected by address lines deposited and fabricated along the back side of the wafer. The back side may also have the dielectric layers slightly etched to facilitate electrical contact with deposited IC address lines.

The front side of the wafer with the self-assembled molecular electronic compounds may have dielectric and control electrodes applied to it using IC-scale techniques. These electrodes may make direct electrical connection with a third terminal of a three-terminal molecular electronic compound.

Alternatively, a second nanoscale layered surface may be placed adjacent the fist nanoscale layered surface to directly connect with the third (and fourth) terminal of the molecular electronic compound already reacted on the first nanoscale columnar wafer surface. The second nanoscale surface will have conductor or semiconductor layers selected to react and electrically connect with the third (and fourth) terminals:

Alternatively, to increase the molecular dimensionality from 1 to 2 dimensions, two wafers like those of the previous Figures, may be faced together at an orthogonal orientation. By compressing the wafers, intimate contact and molecular reaction can be provided on a molecular scale.

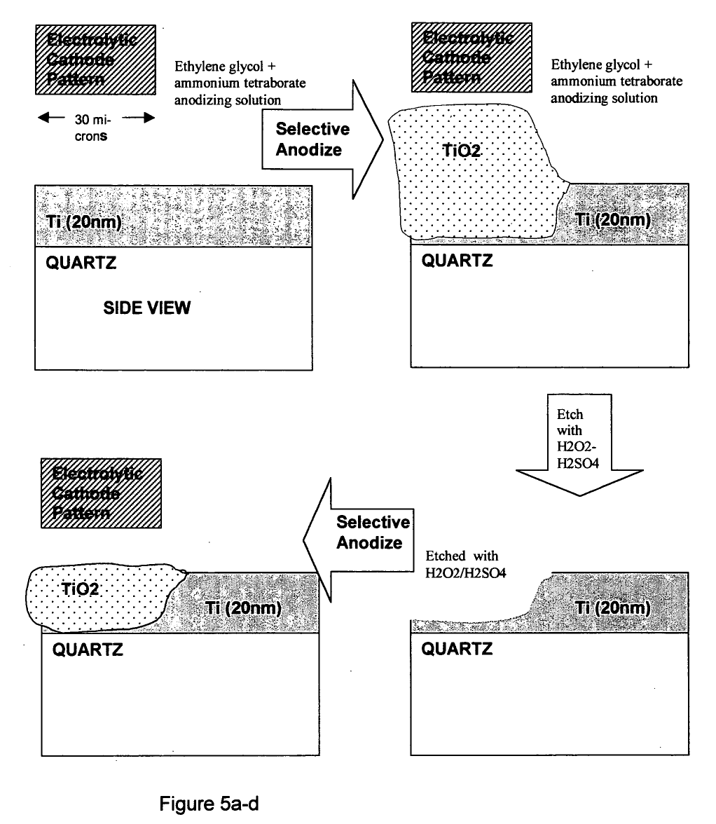

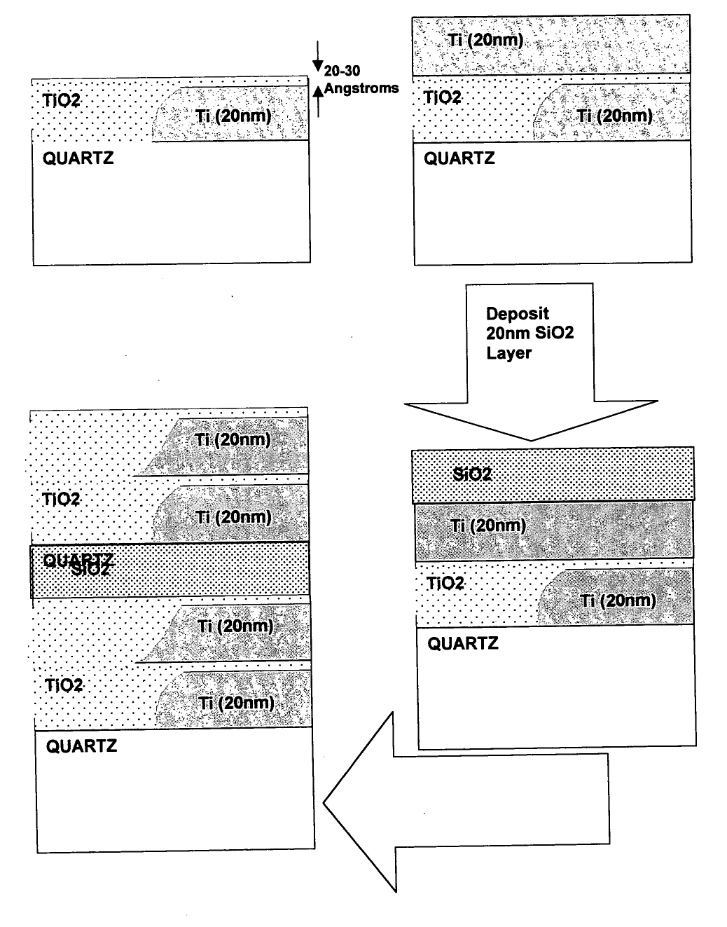

The composition of the top and bottom electrodes may be selected to promote specific attachment, orientation and self-assembly. The separation distance D1 can also be used, for example, to select attachment of terminals 1 and 2 of a multi-terminal molecular electronic compound, but not terminal 3 (or 4), which is too bulky to fit In this way, 3 and 4 terminal molecular compound structures may be fabricated. For example, if the molecular compound used in the device of FIG. 5 is a three terminal compound, with terminals 1 and 2 preferentially and selectively attached to the electrodes, the third terminals may be chemically attached to crossing, adjacent conductors of conventional IC scale, or the conductors of another polished, flat, wafer face placed adjacent thereto. Self-assembly may be assisted by gap-filling chemical reactions.

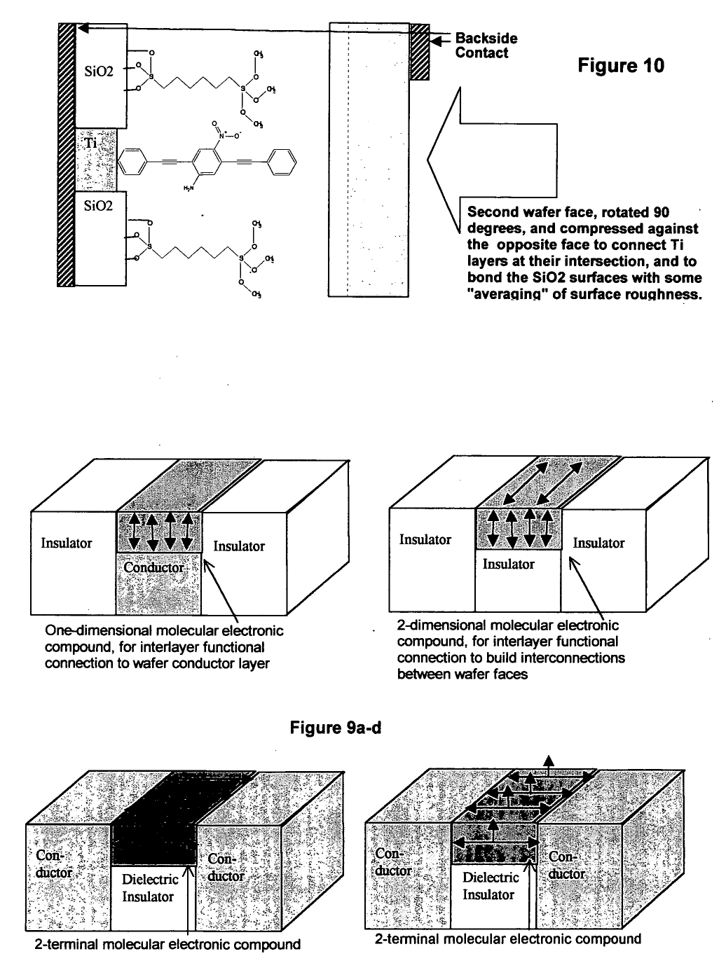

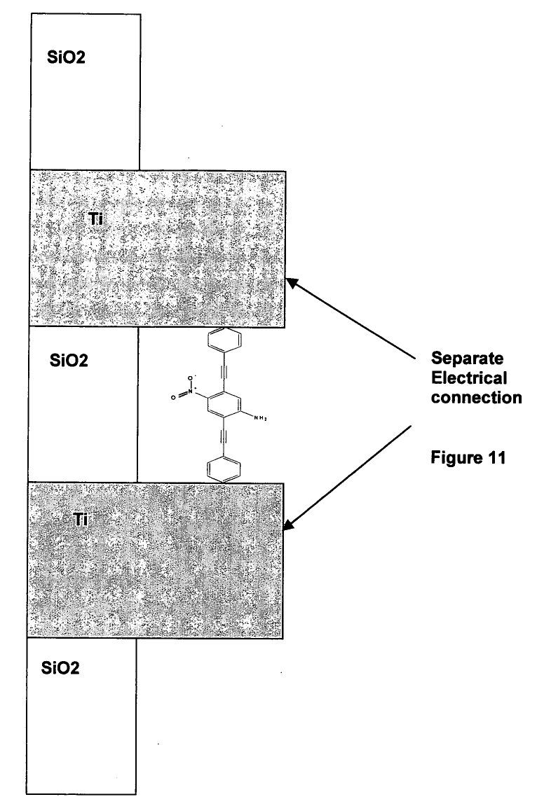

As shown in the following FIG. 9, after (or before) the 2, 3, or 4-terminal molecular electronic compound is self-assembled between the properly-spaced top and bottom electrodes, other self-assembly fabrication molecules may be selective applied to other surfaces. For, example, a molecule (e.g., with trimethyl silanol coupling agent endgroup) which can be applied inertly (e.g., cold) and activated to react with or displace the molecular electronic compound (such as an oxidizing group, etc.) on another surface immediately adjacent to itself. This effectively provides “molecular scale self-disassembly”, which can precisely define molecular-scale active zones along the “top” and “bottom” electrodes, which are self-aligned between control or connecting electrodes of the facing, orthogonal wafer array.

By assembling to wafer faces against each other at a 90 degree angle, like those on the lower right of FIG. 9, self addressed molecular sized zones can be uniquely isolated. The self-assembled oxidizing or other reactive agent will interact with the molecular electronic compound of the other face, at precisely spaced locations between the top and bottom electrodes of the other face, to isolate zones between electrodes on this “blocking” face. This permits addressing very large numbers of molecularly small zones between molecular scale electrode layers, automatically forming active zones between address lines and orthogonal control lines.

It should be noted that if unique backside addressing is not used, that holographic-style memory or devices are created in a pattern across the active face of the system. This could be used to create redundancy for more reliable systems, or unique zones may be addressed in the “z” direction by other addressing. If the N*(N+1)-style addressing system is used, an extremely large number of uniquely addressable sites may be created. For example, 100 “top electrode” and 101 “bottom electrode” back side address lines can uniquely address 10,000 layers of “top” and “bottom” electrodes. By crossing 2 such addressed faces, 100 million unique molecular electronics sites may be uniquely addressed. These thin wafers may be stacked (with cooling) to produce extremely high density systems.

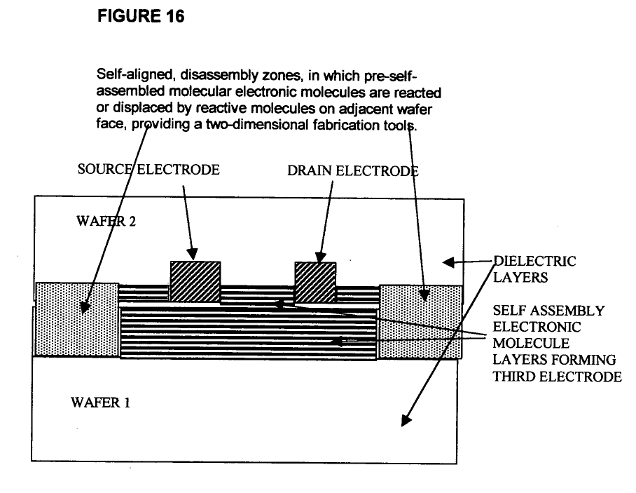

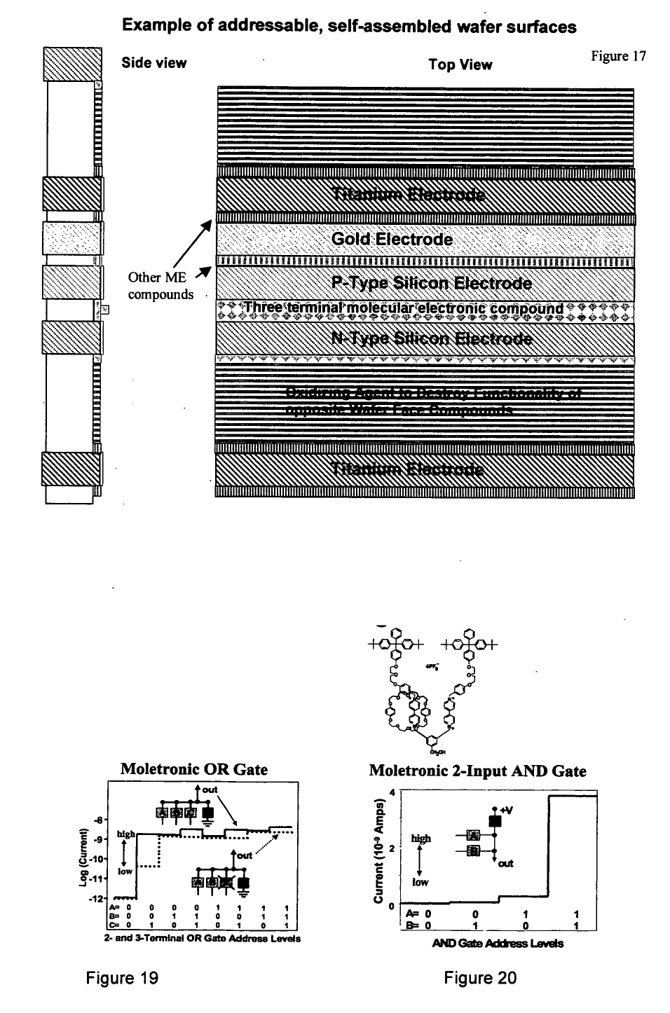

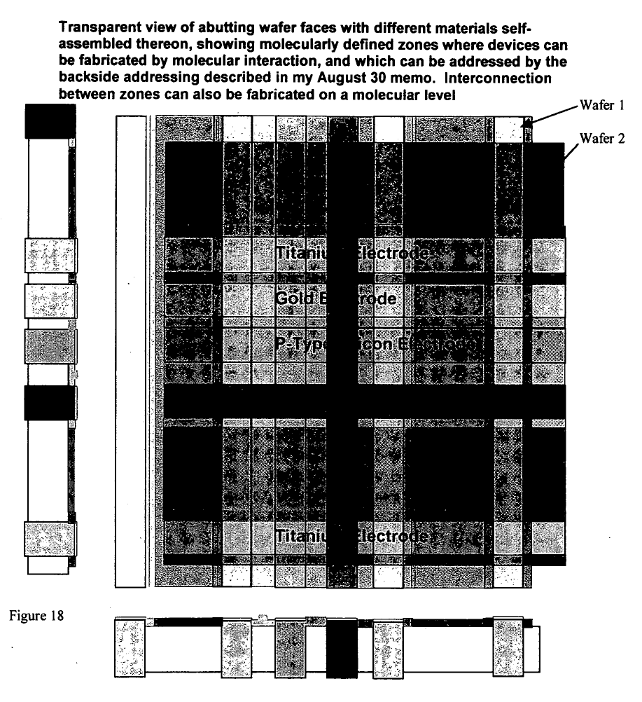

A cross-sectional view of the negatively self-assembled zones produced by orthogonally facing surfaces of FIG. 12, taken through line 16-16, is shown in FIG. 16.

For manufacturing simplicity, and to facilitate buildup of a large number of layer thicknesses on wafers while minimizing thermal stress, wafer layers may be stacked and wafer-bonded, using conventional wafer-bonding techniques. Different layer patterns and different materials may be more easily combined in this manner.

Wafer bonding may be used to economically build thick wafers, and to vary the geometrical patterns available for same-chip device functionality (e.g., for pipelined processing across the chip), can make large-scale wafer fabrication more economical, by stacking large-area layers produced by conventional film-deposition equipment

Abutting Wafer Design and Orientation

In addition to the specific design of the abutting wafers, the rotation angle of the facing wafers may also be varied to achieve different design goals. 90 degree rotation maximizes density, and retains same-layer effects. 45 degree rotation facilitates interlayer functional interaction and connection between the component areas of functional cells.

Processing and Fabrication Technologies

A wide variety of fabrication and processing technologies may be applied. Polishing and etching (chemical, plasma, laser, etc) techniques are well developed.

Further in accordance with the present invention, multi-terminal (3 or more terminals) molecular electronic compounds which are designed to carry out specific logic or similar functions within the molecule itself (see, e.g., the above-cited Mitre publications) may have their respective terminals provided with suitable functional attachment groups “G”, which are preferentially reactive with specific corresponding, respectively multiple zones on the wafer-thickness. By matching the thickness of such zones with the respective lengths between the attachment groups, a powerful chelate-like thermodynamic drive force for precise self-assembly in the desired arrangement is provided.

Wafer Bonding between polished, flat layers is also well developed. Photolithography and IC device fabrication techniques can be used to apply address lines. Self-aligned X-ray processing may also be used at the self-aligned intersection of the layers to process molecular compounds. Examples of conventional molecular electronic memory and logic designs, for fabrication in accordance with the present invention, are as follows:

The proposed addressable, molecular-level self-assembly (and self-disassembly) methods and structures of this disclosure, guided by layer geometry and surface chemistry, offer a wide and robust array of techniques for commercial, large scale device fabrication, and a current solution to the interconnection control and addressing problem of nanoscale electronic device fabrication.

While the present invention has been described with respect to a number of specific embodiments of wafers, assembly methods and molecular compounds, it will be appreciated that a very significantly powerful set of addressing and assembly tools has been provided which will enable a very broad range of applications and designs, all of which are intended to be within the scope of the present invention.

What is claimed is:

1. A method for manufacturing a wafer having conductors separated by distances in the range of from about 1 to about 100 nm for nanoscale electronics, comprising the steps of
depositing sequential layers of conductors, semiconductors and/or dielectrics on a sheath substrate at thicknesses in the range of from about 1 to about 100 nm to form a layered wafer boule patterning at least some of the conductor or semiconductor layers for backside addressing;
cross cutting the wafer boule, and polishing the front and back surfaces to provide a nanoscale wafer.

2. A method in accordance with claim 1 wherein one or more molecular electronic components is self-assembled on the front surface of the nanoscale wafer.

3. A method in accordance with claim 2 wherein two nanoscale wafers are assembled adjacent each other to define molecular electronic zones such as addressable memory or logic gates.

4. A method in accordance with claim 2 wherein at least one of the molecular electronic compounds is a multi-dentate, multi-terminal electronic compound with multiple terminals each with a functional attachment group having a spacing and position corresponding to the spacing and position of a corresponding reactive self-assembly surface on a wafer face or adjacent wafer face, for the respective functional group.
